(19) United States
(12) Patent Application Publication
(10) Pub. No.: US 2020/0296849 A1
(43) Pub. Date: Sep. 17, 2020

(54) STAND

(71) Applicant: FUJITSU CLIENT COMPUTING LIMITED, Kanagawa (JP)

(72) Inventors: Ryohei Sato, Kawasaki (JP); Ikki Tatsukami, Kawasaki (JP); Yuko Hirao, Kawasaki (JP); Frank Müller Augste, Munchen (DE); Albert Jiang, Munchen (DE); Morris Sung, Munchen (DE)

(73) Assignee: FUJITSU CLIENT COMPUTING LIMITED, Kanagawa (JP)

(21) Appl. No.: 16/795,899

(22) Filed: Feb. 20, 2020

(30) Foreign Application Priority Data
Mar. 14, 2019 (JP) 2019-046981

(51) Int. Cl. H05K 5/02; G06F 1/18

(52) U.S. Cl. CPC H05K 5/0234; G06F 1/181

(57) ABSTRACT

A stand includes a base that is attached to a first wall of a housing of an electronic device and extends between a mounting surface and the first wall; and a first support that is located at one of opposite ends of the base in a first direction along the mounting surface, and faces one of a second wall pair standing on both sides of the housing in the first direction.

### CROSS-REFERENCE TO RELATED APPLICATIONS

This application is based upon and claims the benefit of priority from Japanese Patent Application No. 2019-046981, filed Mar. 14, 2019, the entire contents of which are incorporated herein by reference.

### FIELD

Embodiments described herein relates generally to a stand.

### BACKGROUND

Conventionally, stands for attachment to the housing of an electronic device are known. Such a stand includes a base attached to a first wall of the housing of an electronic device and two supports located on opposite ends of the base in a first direction and facing a second wall pair on both sides of the housing in the first direction.

It is beneficial to provide a stand of a novel structure that can save an installation space, for example.

It is thus preferable to provide a stand of a novel structure that can save an installation space.

### SUMMARY

According to one aspect of this disclosure, a stand includes a base that is attached to a first wall of a housing of an electronic device and extends between a mounting surface and the first wall; and a first support that is located at one of opposite ends of the base in a first direction along the mounting surface, and faces one of a second wall pair standing on both sides of the housing in the first direction.

### BRIEF DESCRIPTION OF THE DRAWINGS

FIG. 1 is an exemplary perspective view of a stand according to one or more embodiments attached to a housing of an electronic device in a first posture and in a first state, with a first component separated from a second component;

FIG. 2 is another exemplary perspective view of the stand in one or more embodiments;

FIG. 3 is an exemplary exploded perspective view of the stand in one or more embodiments;

FIG. 4 is an exemplary perspective view of the housing of the electronic device to which the stand of one or more embodiments is attached, as viewed from an angle different from that in FIG. 1;

FIG. 5 is an exemplary side view of the stand of one or more embodiments attached to the housing of the electronic device in a second posture and in the first state, with the first component separated from the second component;

FIG. 6 is another exemplary side view of the stand of one or more embodiments attached to the housing of the electronic device in a second state, with the first component united with the second component;

FIG. 7 is an exemplary side view of the stand in FIG. 1, with the housing tilting oppositely to a wall surface; and

FIG. 8 is another exemplary side view of the stand in FIG. 1 with the housing tilting toward the wall surface.

### DETAILED DESCRIPTION

The features according to one or more embodiments described below and functions and effects attained by the features are presented for illustrative purposes only. One or more embodiments can be implemented by features other than the ones disclosed herein. One or more embodiments can implement at least one of the effects including derivative effects attained by the features.

Throughout this disclosure, ordinal numbers are used to distinguish parts, components, members, portions, positions, directions, and else, and are not intended to indicate order or priority.

### Embodiments

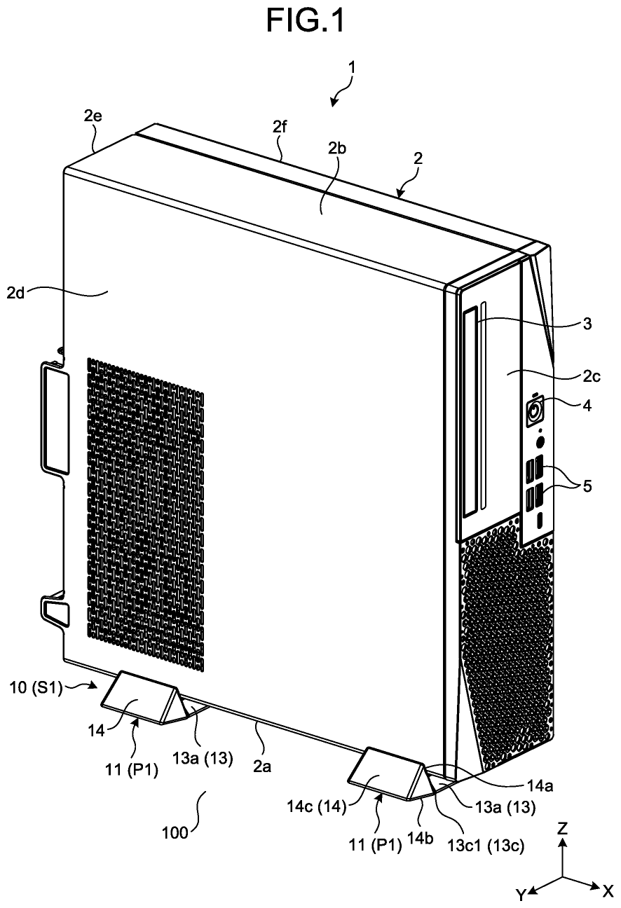

FIG. 1 is a perspective view of a stand 10 according to one or more embodiments. The stand 10 is attached to a housing 2 of an electronic device 1 in a first posture P1 and in a first state S1, with a first component 11 separated from a second component 12. As illustrated in FIG. 1, the stand 30 is attached to the housing 2 of the electronic device 1 such as a computer tower of a desktop computer, for example. The stand 30 stands between the housing 2 and a mounting surface 100 of, for example, a desk, a counter, or a rack to support the housing 2 upright.

In the following, three orthogonal directions, X-direction, Y-direction, and Z-direction are defined for easier understanding. X-direction is along the depth or in anteroposterior direction of the housing 2 and along the width or transverse length of the stand 30. Y-direction is along the width (horizontal length) of the housing 2 and along the length of the stand 30. Z-direction is along the height (vertical length) of the housing 2 and along the height (thickness or vertical length) of the stand 30.

The Y-direction is an exemplary first direction along the mounting surface 100. The Z-direction is an exemplary second direction crossing the first direction. The X-direction is an exemplary third direction crossing the first direction and the second direction. In the following description, the X-direction may be referred to as a frontward direction. The opposite direction of the X-direction may be referred to as a rearward direction. The Y-direction may be referred to as a leftward direction. The opposite direction of the Y-direction may be referred to as a rightward direction. The Z-direction may be referred to as an upward direction. The opposite direction of the Z-direction may be referred to as a downward direction.

As illustrated in FIG. 1, the housing 2 has, for example, a flat, rectangular-cuboid shape in the Y-direction. The housing 2 includes a plurality of walls such as a bottom wall 2a, a top wall 2b, a front wall 2c, a left wall 2d, a rear wall 2e, and a right wall 2f. The bottom wall 2a may be referred to as a lower wall, and the top wall 2b may be referred to as an upper wall. The front wall 2c, the left wall 2d, the rear wall 2e, and the right wall 2f may be referred to as sidewalls or peripheral walls.

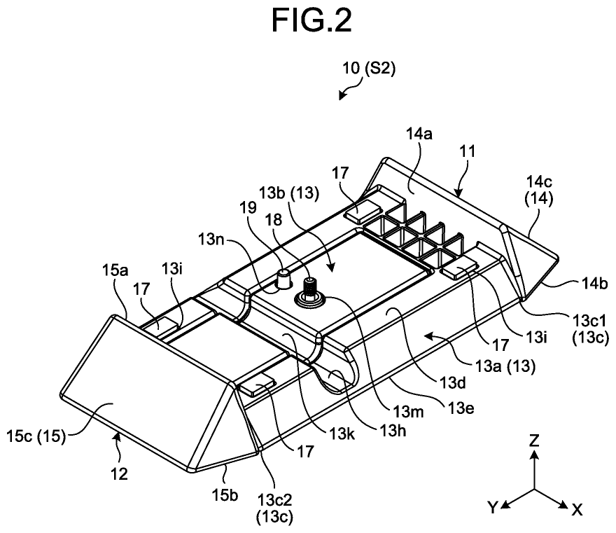

The bottom wall 2a and the top wall 2b extend in a direction orthogonal to the Z-direction, or extend along an XY plane, and are spaced apart in parallel from each other in the Z-direction. The bottom wall 2a serves as the bottom end of the housing 2 and the top wall 2b serves as the top end of the housing 2. The stand 10 includes a base 13, as described later, which is fastened to the bottom wall 2a with fasteners 18 (see FIG. 2) such as screws or bolts. The bottom wall 2a is an exemplary first wall.

The front wall 2c and the rear wall 2e extend in a direction orthogonal to the X-direction, or extend along an YZ plane, and are spaced apart in parallel from each other in the X-direction. The front wall 2c extends between the X-directional ends of the bottom wall 2a and the top wall 2b. The rear wall 2e extends between the opposite ends of the bottom wall 2a and the top wall 2b in the X-direction. The front wall 2c serves as the front end of the housing 2 and the rear wall 2e serves as the rear end of the housing 2. The front wall 2c (see FIG. 1) is equipped with, for example, an optical disc drive 3, a power button 4, and connectors 5.

The left wall 2d and the right wall 2f extend in a direction orthogonal to the Y-direction, or extend along an XZ plane, and are spaced apart in parallel from each other in the Y-direction. The left wall 2d extends between the Y-directional ends of the bottom wall 2a and the top wall 2b. The right wall 2f extends between the opposite ends of the bottom wall 2a and the top wall 2b in the Y-direction. The left wall 2d serves as the left end of the housing 2 and the right wall 2f serves as the right end of the housing 2. One of the left wall 2d and the right wall 2f faces a support 14 of the stand 10, as described later, and is supported by the support 14. The left wall 2d and the right wall 2f are an exemplary second wall.

FIG. 2 is a perspective view of the stand 10. As illustrated in FIG. 2, the stand 10 includes the base 13 and a pair of supports 14 and 15, for example. The base 13 has a rectangular plate shape extending along the bottom wall 2a. The base 13 has an upper surface 13d in the Z direction and a lower surface 13e in the opposite direction of the Z direction. The upper surface 13d faces the bottom wall 2a while the lower surface 13e faces the mounting surface 100.

Elastic members 17 are provided at the four corners of the upper surface 13d, to elastically support the bottom wall 2a. The elastic members 17 are made of elastomer or rubber, for example. The elastic members 17 at least partially protrude from the upper surface 13d in the Z direction to be accommodated in respective recesses 13i in the base 13. The elastic members 17 are also referred to as buffers or cushions, for example.

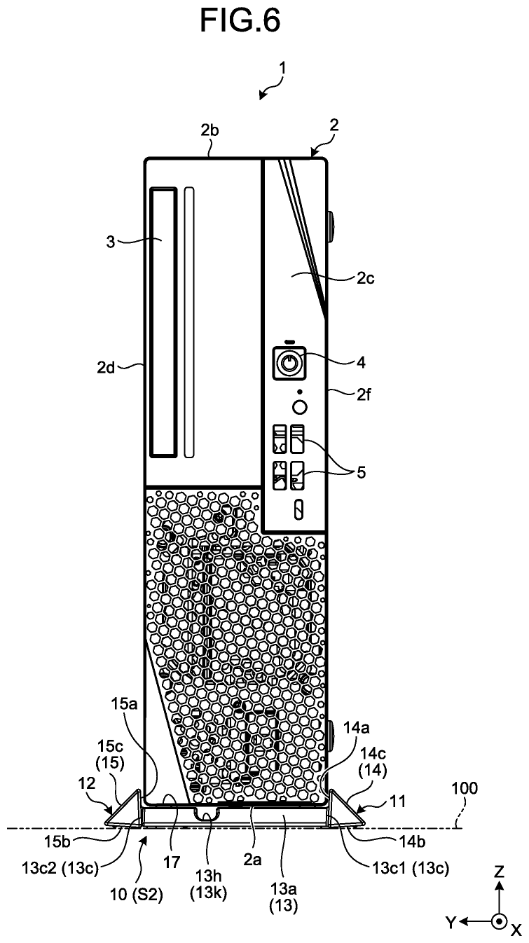

The support 14 is located at one end 13c1 of opposite ends 13c of the base 13 in the Y direction. The support 15 is located at the other end 13c2 of the opposite ends 13c opposite the support 14. The supports 14 and 15 protrude from the base 13 to both sides (outside) of the housing 2 (refer to FIG. 6) in the Y direction and in the Z direction, to support the left wall 2d and the right wall 2f, respectively. The support 14 is an exemplary first support, and the support 15 is an exemplary second support. The supports 14 and 15 may be referred to as protrusions or overhangs, for example.

As illustrated in FIG. 2, the supports 14 and 15 has a substantially triangular prism shape as a whole, extending in the X direction, for example. In one or more embodiments, the supports 14 and 15 are plane-symmetric with respect to a virtual symmetry plane passing the Y-directional center of the base 13 and orthogonal to the Y direction. The supports 14 and 15 are in mirror-image relationship. The support 14 includes a side surface 14a, a lower surface 14b, and a tilted surface 14c. The support 15 includes a side surface 15a, a lower surface 15b, and a tilted surface 15c.

The side surface 14a of the support 14 is on the housing 2 side (refer to FIG. 6) and faces the lower end of the left wall 2d. The side surface 15a of the support 15 is on the housing 2 side and faces the lower end of the right wall 2f. The tilted surface 14c of the support 14 is on the opposite side of the housing 2, and extends in a tilted manner from the Z-directional end of the side surface 14a to the opposite end of the lower surface 14b relative to the base 13. The tilted surface 15c of the support 15 is on the opposite side of the housing 2, and extends in a tilted manner from the Z-directional end of the side surface 15a to the opposite end of the lower surface 15b relative to the base 13. The side surfaces 14a and 15a may be referred to as support surfaces, for example.

The lower surfaces 14b and 15b of the support 14 and the support 15 are both in the opposite direction of the Z direction and face a mounting surface 100. In one or more embodiments, the lower surfaces 14b and 15b are tilted such that the further away from the base 13 outward in the Y direction and the opposite direction the lower surfaces 14b and 15b are, the further away from the mounting surface 100 they are. The lower surfaces 14b and 15b each include a contact part or region with the mounting surface 100 and a non-contact part or region apart from the mounting surface 100. The lower surfaces 14b and 15b are an exemplary first surface.

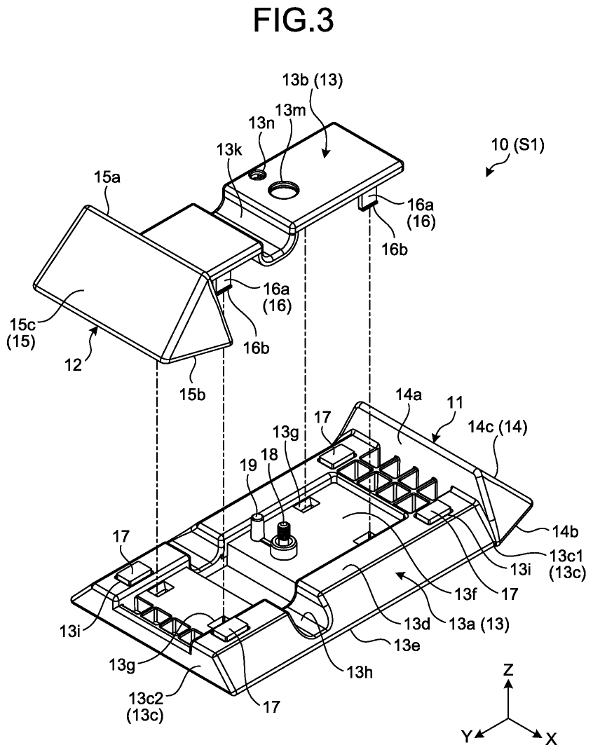

FIG. 3 is an exploded perspective view of the stand 10. As illustrated in FIG. 3, the stand 10 includes the first component 11 and the second component 12, for example. The first component 11 includes at least the support 14 and a first part 13a serving as part of the base 13. The second component 12 includes at least the support 15 and a second part 13b serving as part of the rest of the base 13.

In one or more embodiments, the stand 10 is usable in the first state S1 that the first component 11 is separated from the second component 12 and in a second state S2 (refer to FIG. 2) that the first component 11 is united with the second component 12. This improves the degrees of freedom in usage form or mode of the stand 10. The first component 11 may be referred to as a main component or a base component, for example. The second component 12 may be referred to as a sub-component, for example.

As illustrated in FIG. 3, the second part 13b is to be placed on the first part 13a in the Z direction. The second part 13b is provided with hooks 16 that protrude in the opposite direction of the Z direction. The first part 13a is provided with openings 13g through which the hooks 16 pass. The first component 11 and the second component 12 are detachably coupled to each other by snap fit, that is, fitting between tabs 16b of the hooks 16 and the periphery of the openings 13g.

The hooks 16 are located at four corners of the second part 13b, for example. The hooks 16 each include a protrusion 16a and the tab 16b. The protrusion 16a passes through the opening 13g in the Z direction and the tab 16b is fitted into a lower surface 13e side of the opening 13g. Each tab 16b protrudes outwardly (outside the protrusion 16a) in the X direction away from the second part 13b of the protrusion 16a.

The second part 13b is provided with a recess 13k. The recess 13k has a substantially U-shape opening in the Z direction, as viewed in the X direction. The recess 13k is offset from the center of the second part 13b in the Y direction (on the support 15 side), and extends in the X direction. The recess 13k bends in a convex shape from the wall of the second part 13b in the opposite direction of the Z direction. The recess 13k is an exemplary second passage, and may be referred to as a bend, for example.

The second part 13b is provided with through holes 13m and 13n passing in the Z direction. The through holes 13m and 13n are aligned with spacing in the X direction. As illustrated in FIG. 2, the fastener 18 is inserted into the through hole 13m to couple the base 13 and the bottom wall 2a together while a protrusion 19, as described later, of the first part 13a is inserted into the through hole 13n. The through holes 13m and 13n may be referred to as clearance holes, for example.

As illustrated in FIG. 3, the first part 13a is provided with recesses 13f and 13h that are dented from the upper surface 13d in the opposite direction of the Z direction. The recess 13f is located at substantially the center of the first part 13a in the X direction and extends in the Y direction. The recess 13f can accommodate the second part 13b. In one or more embodiments, while the second part 13b is accommodated in the recess 13f, i.e., in the second state S2 (refer to FIG. 2) that the first component 11 and the second component 12 are united together, the upper surface 13d of the first part 13a and the upper surface 13d of the second part 13b are flush with each other in the X direction.

The recess 13h is offset from the center of the first part 13a in the Y direction (toward the support 15 of the first part 13a) and corresponds to the recess 13k. The recess 13h can contain the recess 13k. The recess 13h extends between both X-directional ends of the first part 13a across the recess 13f (refer to FIG. 3) and the bottom of the recess 13f, and passes through the first part 13a in the X direction. In the Z-direction, the recess 13h has a deeper depth at an X-directional center (the part accommodating the recess 13k) than the X directional, opposite ends. The recess 13h is an exemplary first passage.

In one or more embodiments, the recesses 13h and 13k communicate with each other in the X direction in the second state S2 (refer to FIG. 2) that the first component 11 and the second component 12 are united. The recesses 13h and 13k can accommodate a cable that connects the housing 2 of the electronic device 1 and a keyboard or a mouse, for example. The recesses 13h and 13k may be referred to as wiring passages, gaps, or openings, for example.

As illustrated in FIG. 3, the bottom of the recess 13f is provided with the openings 13g. The openings 13g are located at four corners of the recess 13f and corresponds to the hooks 16, passing the first part 13a in the Z direction, for example. The lower surface 13e side of the opening 13g is fitted with the tab 16b of the hook 16. An operator can easily release the engagement between the hook 16 and the opening 13g by pressing the tab 16b from the lower surface 13e of the base 13.

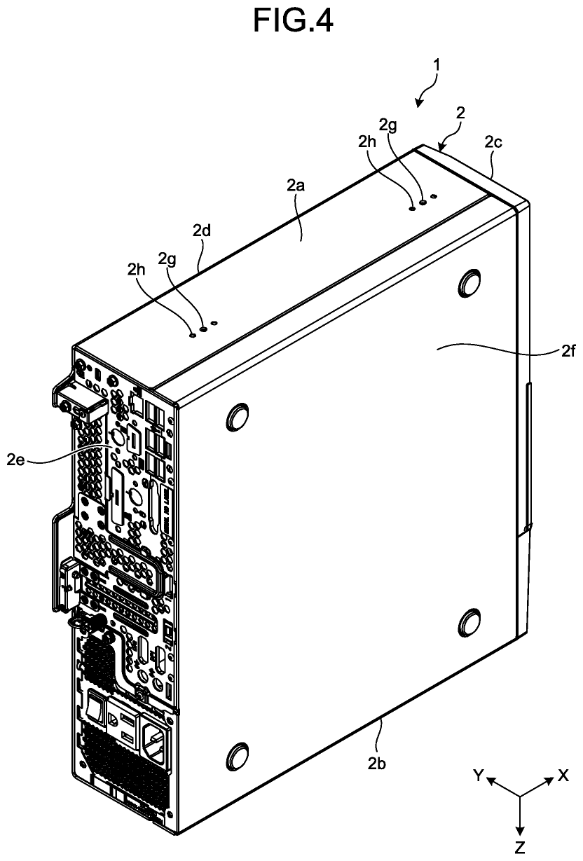

The bottom of the recess 13f is provided with the protrusion 19 that corresponds to the through hole 13n. The protrusion 19 is offset in the opposite direction of the X direction from the fastener 18, which is located at the X-directional center of the first part 13a. The protrusion 19 has a cylindrical shape along the periphery of an opening 2h (refer to FIG. 4) in the bottom wall 2a, for example. The protrusion 19 may be referred to as a first positioner or an engaging pin, for example.

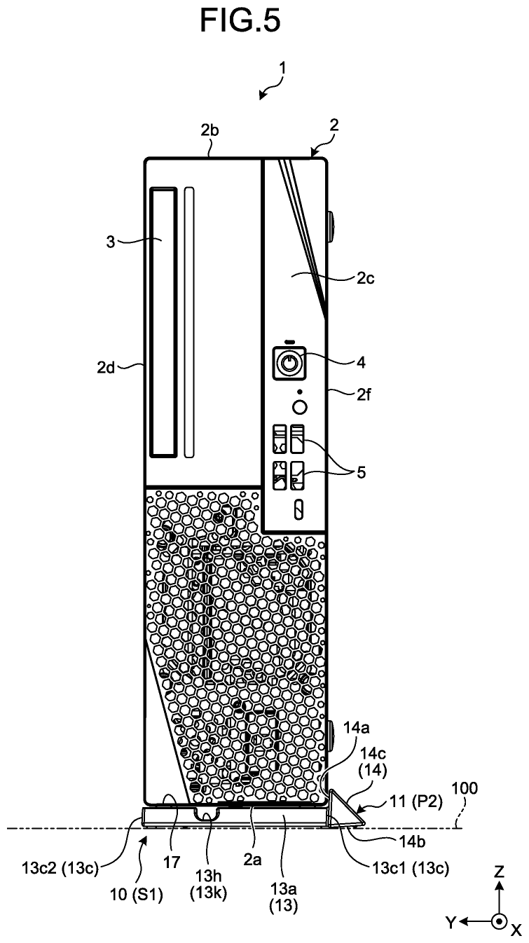

FIG. 4 is a perspective view of the housing 2 of the electronic device 1, as viewed from an angle different from that in FIG. 1. FIG. 5 is a side view of the stand 10. In FIG. 5, the stand 10 is attached to the housing 2 in a second posture P2 and in the first state S1 that the first component 11 is separated from the second component 12. FIG. 6 is another side view of the stand 10. In FIG. 6, the stand 10 is attached to the housing 2 in the second state S2 that the first component 11 is united with the second component 12.

As illustrated in FIG. 4, the bottom wall 2a is provided with central holes 2g and two pairs of openings 2h. The central holes 2g are provided to opposite ends of the bottom wall 2a in the X direction, for example. The inner surface of the central hole 2g is provided with a female screw that engages with a male screw of the fastener 18 to connect the bottom wall 2a and the base 13. In one or more embodiments, two stands 10 (refer to FIG. 1) are attachable to the bottom wall 2a corresponding to the central holes 2g.

As illustrated in FIG. 4, the openings 2h are located at both ends of the bottom wall 2a across the central holes 2g in the X direction. In other words, the openings 2h are arranged around the axis of the central holes 2g with 180-degree intervals. The openings 2h are recesses opening in the opposite direction of the Z direction, i.e., toward the stand 10. The protrusion 19 (refer to FIG. 3) is inserted into the openings 2h. The openings 2h may be referred to as a second positioner, for example.

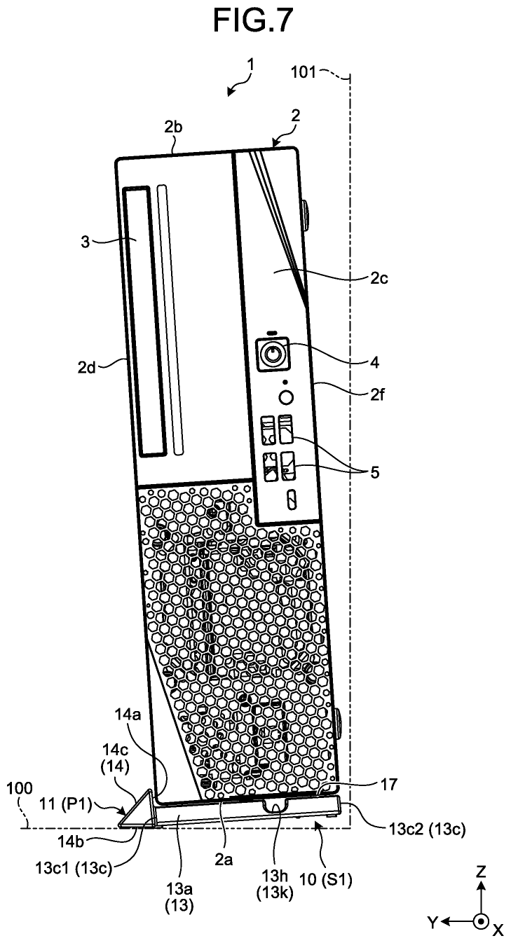

In one or more embodiments, the protrusion 19 and one of the openings 2h are fitted together to position the first component 11 on the bottom wall 2a in the first state S1 and in the first posture P1 (refer to FIGS. 1 and 7). The protrusion 19 and the other of the openings 2h are fitted together to position the first component 11 on the bottom wall 2a in the first state S1 and in the second posture P2 (refer to FIG. 5). In the first posture P1, the support 14 of the first component 11 faces the left wall 2d. In the second posture P2, the support 14 faces the right wall 2f.

In one or more embodiments, by fitting between one of the openings 2h and the protrusion 19, the stand 10 can be positioned on the bottom wall 2a in the second state S2 (refer to FIG. 6). Thus, the stand 10 of one or more embodiments is usable in multiple modes including the first posture P1 (refer to FIGS. 1 and 7) in which the support 14 supports the left wall 2d, the second posture P2 (refer to FIG. 5) in which the support 14 supports the right wall 2f, and the second state S2 (refer to FIG. 6) in which the support 14 supports the right wall 2f and the support 15 supports the left wall 2d.

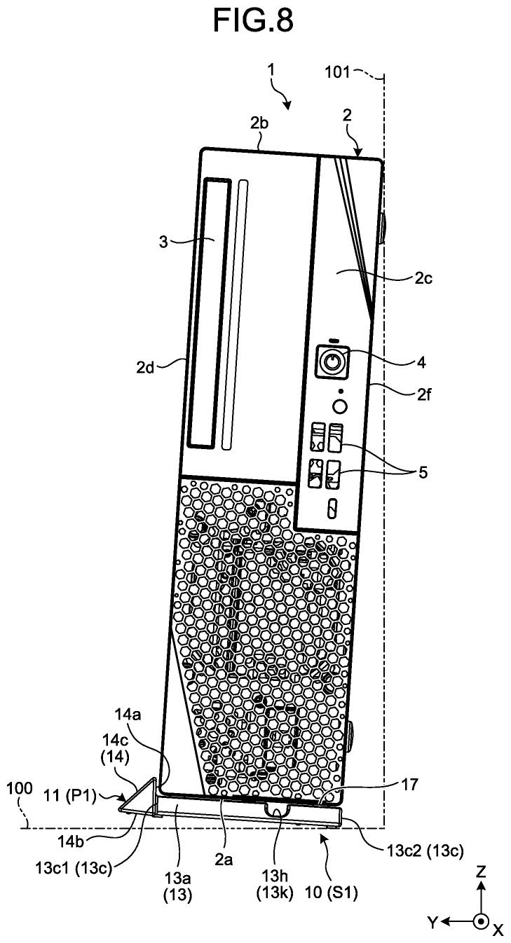

FIG. 7 is a side view of the stand 10 in FIG. 1. In FIG. 7, the housing 2 is tilted oppositely to a wall surface 101. FIG. 8 is another side view of the stand 10 in FIG. 1. In FIG. 8, the housing 2 is tilted toward the wall surface 101. As illustrated in FIGS. 7 and 8, in one or more embodiments, the housing 2 of the electronic device 1 is installed near the wall surface 101 intersecting the mounting surface 100 through the stand 10.

As illustrated in FIG. 7, in one or more embodiments, when the housing 2 is tilted with respect to the mounting surface 100 oppositely to the wall surface 101 due to an event such as an earthquake, for example, the lower surface 14b (tilted surface) of the support 14 becomes parallel to the mounting surface 100 and substantially entirely contacts the mounting surface 100. This prevents the housing 2 from further tilting oppositely to the wall surface 101 after the contact between the lower surface 14b and the mounting surface 100. The support 14 may be referred to as an inclination preventer, for example.

In one or more embodiments, as illustrated in FIG. 8, when the housing 2 is tilted with respect to the mounting surface 100 toward the wall surface 101, the end (right corner) of the housing 2 contacts the wall surface 101. This prevents the housing 2 from being further tilted toward the wall surface 101 after the contact between the housing 2 and the wall surface 101.

As described above, the stand 10 of one or more embodiments includes the base 13 that is attached to the bottom wall 2a (first wall) of the housing 2 of the electronic device 1 and extends between the mounting surface 100 and the bottom wall 2a, and the support 14 (first support) located at one end 13c1 of opposite ends 13c of the base 13 in the Y direction (first direction) along the mounting surface 100 and facing one of the left wall 2d and the right wall 2f (second walls) on both sides of the housing 2 in the Y direction.

Owing to such a structure, to place the housing 2 of the electronic device 1 near the wall surface 101 intersecting the mounting surface 100, the stand 10 can omit the support on the wall surface 101 side, unlike the conventional structure. Thereby, the base 13 and the housing 2 are placed closer to the wall surface 101. Consequently, it is made possible to provide the stand 10 of a novel structure that can save an installation space, for example.

The stand 10 of one or more embodiments includes the first component 11 and the second component 12. The first component 11 includes the first part 13a serving as part of the base 13 and the support 14. The second component 12 includes the second part 13b and the support 15, and is detachable from the first component 11. The second part 13b serves as part of the base 13 and is to be placed on the first part 13a in the Z direction (second direction) intersecting the mounting surface 100. The support 15 (second support) is located at the other end 13c2 of the base 13 opposite to the support 14, and faces the other of the left wall 2d and the right wall 2f.

Owing to such a structure, the stand 10 is usable in the first state S1, with the second component 12 separated from the first component 11, for example. It is thus possible to provide the stand 10 including the support 14 at one end 13c1 of the base 13 alone. Further, it is possible to provide the stand 10 usable both in the first state S1 that the second component 12 is separated from the first component 11 and in the second state S2 that the second component 12 is united with the first component 11, for example.

In one or more embodiments, the first part 13a is provided with the recess 13h (first passage) that extends in the X direction (third direction) while the second part 13b is provided with the recess 13k (second passage) that communicates with the recess 13h in the X direction in the second state S2 that the second component 12 is united with the first component 11.

Owing to such a structure, it is possible to provide the stand 10 with the recesses 13h and 13k which allow wiring of a cable to connect the housing 2 of the electronic device 1 and a keyboard or a mouse in the first state S1 and the second state S2, for example.

In one or more embodiments, the first component 11 is attachable to the bottom wall 2a in two postures, the first posture P1 in which the support 14 faces the left wall 2d (one wall) and the second posture P2 in which the support 14 faces the right wall 2f (the other wall).

Owing to such a structure, the stand 10 can be placed irrespective of the position of the wall surface 101 relative to the housing 2, i.e., on the right wall 2f side or the left wall 2d side. This can improve the degrees of freedom in layout of the housing 2, for example.

In one or more embodiments, the first component 11 includes the protrusion 19 that protrudes in the Z direction from the first part 13a to position the first component 11 in the first posture P1 and the second posture P2 on the bottom wall 2a.

Owing to such a structure, the protrusion 19 works to position the first component 11 in both the first posture P1 and the second posture P2, for example, which enables easier, more smooth, and more accurate attachment of the first component 11 to the bottom wall 2a.

In one or more embodiments, the supports 14 and 15 each face the mounting surface 100. The supports 14 and 15 have the lower surface 14b and the lower surface 15b (first surfaces), respectively. The lower surface 14b and the lower surface 15b are tilted in such a manner that the further away from the base 13 they are, the further away from the mounting surface 100 they are.

Owing to such a structure, in the case that the housing 2 is tilted due to vibration, the contact between the lower surface 14b and the lower surface 15b, and the mounting surface 100 can work to prevent the housing 2 from being further tilted, for example. Thus, the housing 2 improves in terms of stability.

According to one aspect of this disclosure, it is possible to provide a stand of a novel structure that can save an installation space.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A stand comprising:
a base that is attached to a first wall of a housing of an electronic device and extends between a mounting surface and the first wall; and
a first support that is located at one of opposite ends of the base in a first direction along the mounting surface, and faces one of a second wall pair standing on both sides of the housing in the first direction.

2. The stand according to claim 1, further comprising:
a first component comprising a first part serving as part of the base, and the first support; and
a second component being detachable from the first component and comprising:
a second part serving as part of the base and to be disposed on the first part in a second direction intersecting the mounting surface, and
a second support that is disposed at one end of the second part opposite the first support, and faces the other of the second wall pair.

3. The stand according to claim 2, wherein
the first part is provided with a first passage that extends in a third direction intersecting the first direction and the second direction, and
the second part is provided with a second passage that communicates with the first passage in the third direction while the second component is united with the first component.

4. The stand according to claim 2, wherein
the first component is attachable to the first wall in a first posture and in a second posture, the first posture in which the first support faces one of the second wall pair, the second posture in which the first support faces the other second wall pair.

5. The stand according to claim 4, wherein
the first component comprises a protrusion that protrudes from the first part in the second direction to position the first component relative to the first wall in the first posture and in the second posture.

6. The stand according to claim 1, wherein
at least one of the first support and the second support comprises a first surface that faces the mounting surface, and is tilted in such a manner that the further away from the base the first surface is, the further away from the mounting surface the first surface is.
